(19) United States
(12) Patent Application Publication
(10) Pub. No.: US 2021/0175145 A1
(43) Pub. Date: Jun. 10, 2021

(54) ELECTRONIC CONTROL DEVICE

(71) Applicant: HITACHI AUTOMOTIVE SYSTEMS, LTD., Hitachinaka-shi, Ibaraki (JP)

(72) Inventors: Minami TERANISHI, Tokyo (JP); Shinya KAWAKITA, Tokyo (JP); Hideyuki SAKAMOTO, Hitachinaka-shi (JP)

(73) Assignee: HITACHI AUTOMOTIVE SYSTEMS, LTD., Hitachinaka-shi, Ibaraki (JP)

(21) Appl. No.: 16/769,642

(22) PCT Filed: Nov. 16, 2018
(86) PCT No.: PCT/JP2018/042584

§ 371 Date: Jun. 4, 2020

(30) Foreign Application Priority Data
Dec. 11, 2017 (JP) 2017-237265

(51) Int. Cl. H01L 23/373; H05K 7/20; H01L 23/00; H01L 23/522

(52) U.S. Cl. CPC H01L 23/373; H05K 7/20; H01L 23/562; H01L 2224/73253; H01L 24/14; H01L 2924/15311; H01L 23/5226

(57) ABSTRACT

An electronic control device includes a substrate, a heat generating component mounted on the substrate, a heat dissipation unit thermally coupled to a surface of the heat generating component located on a side opposite to the substrate side, and a cooling mechanism thermally coupled to the heat dissipation unit. The heat dissipation unit includes a porous thermal conductor and a semi-cured resin which includes a heat conductive filler and is formed between at least the porous thermal conductor and the surface of the heat generating component.

### TECHNICAL FIELD

The present invention relates to an electronic control device.

### BACKGROUND ART

An electronic control device used for engine control, motor control, automatic transmission control, and the like is mounted on a vehicle such as an automobile. The electronic control device includes a heat generating component such as a semiconductor element that has a high temperature. Such a heat generating component is generally interposed between a circuit board and a heat dissipation case including a heat dissipation unit such as a heat dissipation fin. In recent years, in such a semiconductor element used in an in-vehicle electronic control device, a housing volume is reduced due to miniaturization, while an amount of heat generation is increased due to high performance. Therefore, it is required to further improve heat dissipation performance of an electronic control device in which a control semiconductor element is accommodated in a heat dissipation case so as not to exceed a guarantee temperature of the semiconductor element or the like.

A structure relating to a single semiconductor device is known in which a heat dissipation sheet is disposed on a semiconductor element that has high temperature, a heat dissipation unit is interposed between the semiconductor element and the heat dissipation sheet, and around the heat dissipation unit is sealed with a resin. The heat dissipation unit includes a heat dissipation member in which a large number of pores are formed in a block-shaped material, and a solder layer interposed between a lower surface of the heat dissipation member and the semiconductor element and between an upper surface of the heat dissipation member and the heat dissipation sheet (for example, see FIG. 16 in PTL 1).

### CITATION LIST

### Patent Literature

PTL 1: JP-A-2012-151172

### SUMMARY OF INVENTION

### Technical Problem

In the electronic control device, the heat generating component such as the semiconductor element is interposed between the circuit board and the heat dissipation case, and a load acts on the heat generating component due to deformation or vibration caused by heat of the circuit board or the like. Since the invention described in PTL 1 relates to the structure of the single semiconductor device, it is not possible to reduce the load acting on the heat generating component due to deformation or vibration caused by heat, or to ensure reliability since the heat generating component is impaired or characteristics are deteriorated.

### Solution to Problem

According to an aspect of the invention, an electronic control device includes a substrate, a heat generating component mounted on the substrate, a heat dissipation unit thermally coupled to a surface of the heat generating component located on a side opposite to the substrate side, and a cooling mechanism thermally coupled to the heat dissipation unit. The heat dissipation unit includes a porous thermal conductor and a semi-cured resin which includes a heat conductive filler and is formed between at least the porous thermal conductor and the surface of the heat generating component.

### Advantageous Effect

According to the invention, a load acting on the heat generating component due to deformation or vibration caused by heat can be reduced and reliability of the heat generating component can be improved.

### BRIEF DESCRIPTION OF DRAWINGS

FIG. 1 is an external perspective view of a first embodiment of an electronic control device of the invention.

FIG. 2 is a cross-sectional view taken along a line II-II of the electronic control device shown in FIG. 1.

FIG. 3 is an enlarged view of a region III of the electronic control device shown in FIG. 2.

FIG. 4 is a cross-sectional view showing an example of a heat generating component.

FIG. 5(a) is an external perspective view of a porous thermal conductor, FIG. 5(b) is an enlarged external schematic view of a region Vb of FIG. 5(a) three-dimensionally showing a pore of the porous thermal conductor, and FIG. 5(c) is a schematic cross-sectional view showing the region shown in FIG. 5(b) in a thickness direction.

FIG. 6 is a diagram showing a heat dissipation effect obtained by the embodiment according to the invention.

FIG. 7 is a cross-sectional view showing a second embodiment of a heat dissipation structure according to the invention.

FIG. 8 is a cross-sectional view showing a third embodiment of the heat dissipation structure according to the invention.

FIG. 9 is a cross-sectional view showing a modification of the heat generating component according to the invention.

FIG. 10(a) is a cross-sectional view showing a fourth embodiment of the heat dissipation structure according to the invention, and FIG. 10(b) is an enlarged view of a heat dissipation component shown in FIG. 10(a).

### DESCRIPTION OF EMBODIMENTS

### First Embodiment

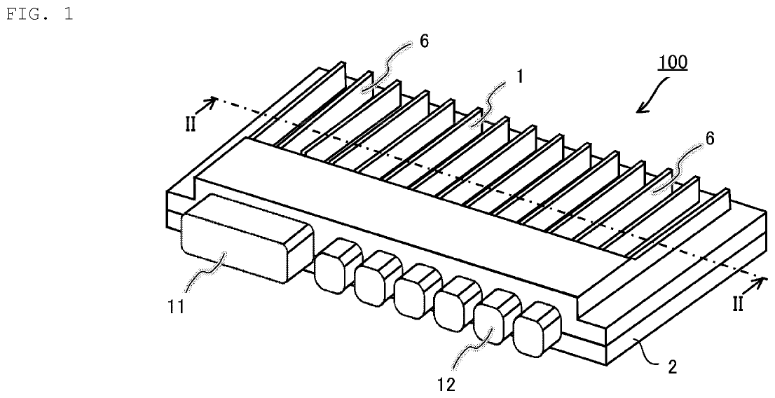

Hereinafter, a first embodiment of the invention will be described with reference to FIGS. 1 to 6.

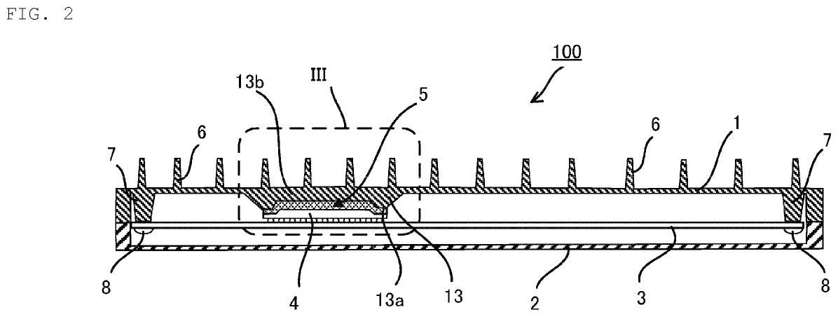

FIG. 1 is an external perspective view of an electronic control device according to the invention. FIG. 2 is a cross-sectional view taken along a line II-II of the electronic control device shown in FIG. 1.

An electronic control device 100 includes a housing including a case main body 1 and a cover 2. The case main body 1 and the cover 2 are fixed by a fastening member such as a screw (not shown). One or a plurality of connectors 11 and a plurality of Ethernet (registered trademark) terminals 12 are disposed on a front surface of the housing. A circuit board 3, a heat generating component 4 including a semiconductor element such as a microcomputer, and a heat dissipation unit 5 are accommodated in the housing.

The case main body 1 is formed of a metal material with excellent thermal conductivity such as aluminum (for example, ADC 12). As shown in FIG. 2, the case main body 1 includes a side wall around, and is formed in a box shape in which a lower surface side (circuit board 3 side) is opened. Boss portions 7 protruding toward the circuit board 3 side are provided at four corner portions in the case main body 1. The circuit board 3 is fixed to end surfaces of the boss portions 7 by screws 8. An upper surface of the case main body 1 is provided with a plurality of heat dissipation fins 6 protruding upward. As shown in FIG. 1, a front surface side of the upper surface of the case main body 1 is a flat portion, and each heat dissipation fin 6 is formed in a plate shape extending from a rear end of the flat portion to a rear side of the case main body 1. The heat dissipation fins 6 and the boss portions 7 are formed integrally with the case main body 1 by casting such as die casting. However, the heat dissipation fins 6 or the boss portions 7 may be manufactured as members separate from the case main body 1 and may be attached to the case main body.

Holes or notches (not shown) for inserting the connector 11 and the Ethernet terminals 12 are formed on a side wall on the front surface side of the case main body 1, and the connector 11 and the Ethernet terminals 12 are connected to a wiring pattern (not shown) formed on the circuit board 3 through the holes or the notches. Power and control signals are transmitted and received between an outside and the electronic control device 100 via the connector 11 and the Ethernet terminals 12.

The heat generating component 4 is mounted on the circuit board 3, and an annular protruding portion 13 protruding toward the circuit board 3 side is formed on an inner surface of an upper portion of the case main body 1. The protruding portion 13 has a substantially trapezoidal shape in a cross section having a wider base portion than a top surface 13a. An inner region of the protruding portion 13 of the case main body 1 is formed as a thick portion 13b having a greater plate thickness than an outer periphery side region of the protruding portion 13. The protruding portion 13 including the thick portion 13b is formed as a part of the case main body 1 by casting. The heat dissipation unit 5 is interposed between the heat generating component 4 and the protruding portion 13 including the thick portion 13b of the case main body 1. A structure of the heat dissipation unit 5 will be described later.

Similar to the case main body 1, the cover 2 is formed of a metal material with excellent thermal conductivity such as aluminum. The cover 2 may be formed of a sheet metal such as iron or a non-metal material such as a resin material to reduce a cost. The holes or notches for inserting the connector 11 or the Ethernet terminals 12 may be formed in the cover 2. Alternatively, a notch serving as a hole may be formed in both of the case main body 1 and the cover 2 in a state where the two members are assembled.

As described above, the heat generating component 4 is mounted on the circuit board 3. Although it is not shown, a passive element such as a capacitor is also mounted on the circuit board 3, and the wiring pattern that connects these electronic components to the connector 11 and the Ethernet terminals 12 is also formed on the circuit board 3. The circuit board 3 is formed of, for example, an organic material such as an epoxy resin. The circuit board 3 is preferably formed of an FR4 material. The circuit board 3 can be a single layer substrate or a multilayer substrate.

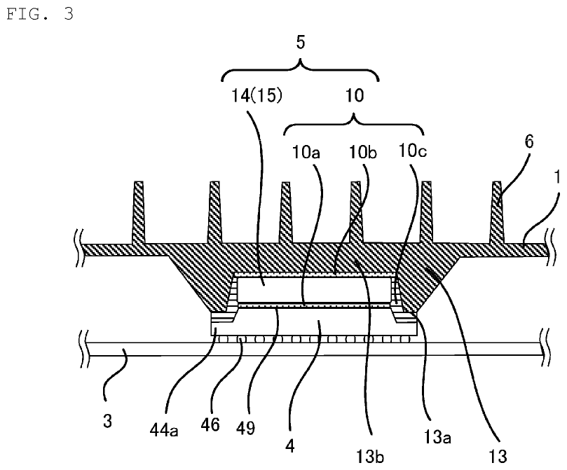

FIG. 3 is an enlarged view of a region III of the electronic control device shown in FIG. 2 and shows details of a heat dissipation structure of the invention.

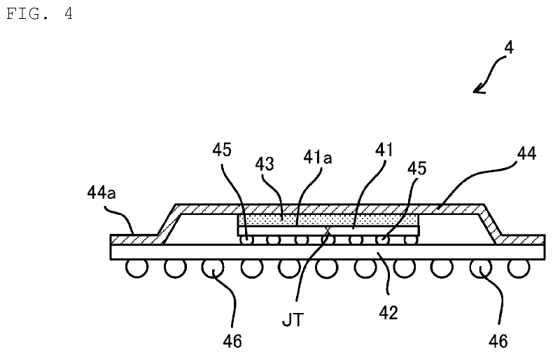

The case main body 1 including the plurality of heat dissipation fins 6 and formed of a metal material with excellent thermal conductivity constitutes a cooling mechanism. As described above, the heat dissipation unit 5 is interposed between the heat generating component 4 and the protruding portion 13 including the thick portion 13b of the case main body 1. The heat dissipation unit 5 includes a heat conduction member 14 and a low elasticity heat dissipation material 10. The low elasticity heat dissipation material 10 includes low elasticity heat dissipation materials 10a, 10b, and 10c. The low elasticity heat dissipation material 10a is formed between a surface 49 (lid 44 in FIG. 4) of the heat generating component 4 on a side opposite to the circuit board 3 side and the heat conduction member 14. The low elasticity heat dissipation material 10b is formed between the heat conduction member 14 and the thick portion 13b of the case main body 1. The low elasticity heat dissipation material 10c is formed between a lower back portion 44a of the heat generating component 4 and the top surface 13a of the protruding portion 13, between an inner peripheral side surface of the protruding portion 13 and an outer peripheral side surface of the heat conduction member 14, and between the inner peripheral side surface of the protruding portion 13 and an outer peripheral side surface of a portion above the lower back portion 44a of the heat generating component 4. As compared with a common thermosetting resin having adhesiveness, the low elasticity heat dissipation materials 10a, 10b, and 10c are semi-cured resins having low elasticity since crosslink density is low. Elastic modulus of the low elasticity heat dissipation materials 10a, 10b, and 10c are about equal to or less than 10 MPa, preferably about 1 MPa. The low elasticity heat dissipation materials 10a, 10b, and 10c contain fillers with excellent thermal conductivity formed of a metal, carbon, a ceramic, or the like. As the low elasticity heat dissipation materials 10a, 10b, and 10c, for example, silicon-based resins containing ceramic fillers are preferable. Although semiconductor device using a thermosetting resin as a sealing resin that seals a semiconductor element is known, such a sealing resin for the semiconductor element has an elastic modulus of a giga Pa level. Unlike the sealing resin having such a high elastic modulus, the low elasticity heat dissipation materials 10a, 10b, and 10c have flexibility so that they can be deformed following deformation or vibration caused by heat of the circuit board 3. Each of the low elasticity heat dissipation materials 10a, 10b, and 10c may be formed of a material having a different resin or filler.

FIG. 4 is a cross-sectional view showing an example of the heat generating component 4.

The heat generating component 4 is a ball grid array (BGA) semiconductor device.

The heat generating component 4 includes a bare semiconductor chip 41 on which an integrated circuit is formed on a main surface 41a side. The semiconductor chip 41 is flip-chip mounted on a substrate 42 by a bonding material 45 such as solder. Above a main surface 41a of the semiconductor chip 41, a sealing resin 43 is formed. The metal lid 44 is formed to cover the sealing resin 43. A peripheral portion of the lid 44 serves as the lower back portion 44a. A plurality of solder balls 46 are formed on a surface of the substrate 42 on a side opposite to the semiconductor chip 41. The integrated circuit formed in the semiconductor chip 41 is connected to the solder balls 46 via the bonding material 45, a wiring pattern (not shown) provided on the substrate 42, and a via (or through hole).

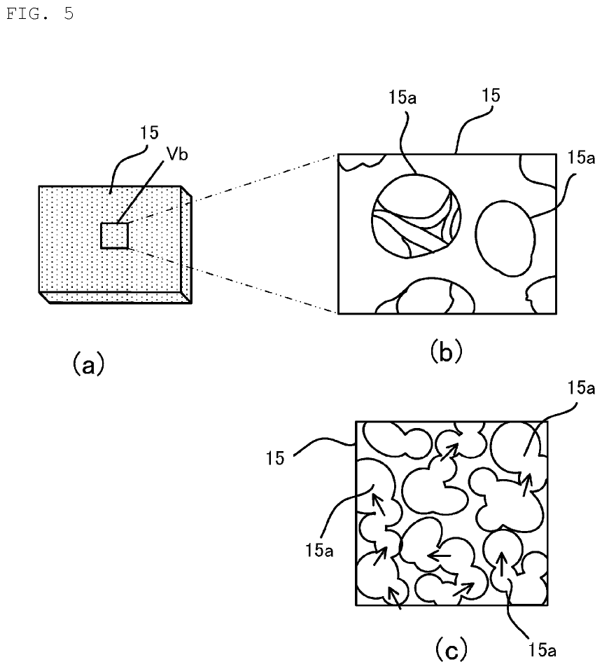

FIG. 5(a) is an external perspective view of a porous thermal conductor, FIG. 5(b) is an enlarged external schematic view of a region Vb of FIG. 5(a) three-dimensionally showing a pore of the porous thermal conductor, and FIG. 5(c) is a schematic cross-sectional view showing the region shown in FIG. 5(b) in a thickness direction.

The heat conduction member 14 is formed of the porous thermal conductor 15 and a low elasticity heat dissipation material (not shown) filled in pores 15a of the porous thermal conductor 15.

As shown in FIG. 5(a), the porous thermal conductor 15 is, for example, a sheet-shaped member formed of a metal such as aluminum or nickel, or a non-metal material having high thermal conductivity such as graphene. As shown in FIGS. 5(b) and 5(c), the porous thermal conductor 15 includes a plurality of pores 15a formed in a continuous manner. Although it is not shown, the low elasticity heat dissipation material is filled in each of the pores 15a of the porous thermal conductor 15. The low elasticity heat dissipation material is formed of the same material as the low elasticity heat dissipation materials 10a, 10b, and 10c. However, the low elasticity heat dissipation material filled in each of the pores 15a of the porous thermal conductor 15 may be formed of a material having a different resin or filler from the low elasticity heat dissipation materials 10a, 10b, and 10c. The porous thermal conductor 15 formed of aluminum or the like generally has a higher thermal conductivity than a resin including the filler with excellent thermal conductivity. By filling the low elasticity heat dissipation material in which the filler with excellent thermal conductivity is dispersed in the pores 15a of the porous thermal conductor 15, the heat conduction member 14 having a higher thermal conductivity than the single porous thermal conductor 15 can be obtained. By using the porous thermal conductor 15 in which the pores 15a are formed continuously, when the low elasticity heat dissipation material is filled in each of the pores 15a, the low elasticity heat dissipation material can be filled in the pores 15a formed in the porous thermal conductor 15 as shown by arrows in FIG. 5(c).

An example of a method of forming the heat dissipation structure shown in FIG. 3 will be described.

A top and a bottom of the case main body 1 are reversed, that is, the inner surface of the case main body 1 is directed upward to form the low elasticity heat dissipation material 10b on the thick portion 13b of the case main body 1. Next, the porous thermal conductor 15 is disposed on the low elasticity heat dissipation material 10b, and the porous thermal conductor 15 is bonded to the low elasticity heat dissipation material 10b. Next, the low elasticity heat dissipation material 10a is formed on an upper surface side of the porous thermal conductor 15. The low elasticity heat dissipation material 10a is formed by being pressed from the upper surface side of the porous thermal conductor 15 so that the low elasticity heat dissipation material 10a is filled in the pores 15a of the porous thermal conductor 15. Next, the low elasticity heat dissipation material 10c is formed around the porous thermal conductor 15. In the formation of the low elasticity heat dissipation material 10c, when the low elasticity heat dissipation material 10a is formed on the porous thermal conductor 15, the low elasticity heat dissipation material 10a is expanded around the porous thermal conductor 15, and the expanded portion can serve as the low elasticity heat dissipation material 10c. The low elasticity heat dissipation material 10c extends to a region corresponding to the top surface 13a of the protruding portion 13. Next, the heat generating component 4 mounted on the circuit board 3 is bonded to the low elasticity heat dissipation materials 10a and 10c.

It should be noted that the porous thermal conductor 15 in which the low elasticity heat dissipation material is filled in advance in the pores 15a may be bonded to the low elasticity heat dissipation material 10b after the low elasticity heat dissipation material 10b is formed on the thick portion 13b of the case main body 1. The above-described method can be appropriately changed.

As shown in FIG. 3, the protruding portion 13 of the case main body 1 is formed in an annular shape along a peripheral portion of the heat generating component 4 and surrounds the heat conduction member 14. The protruding portion 13 of the case main body 1 extends to the heat generating component 4 side so as to cover substantially an entire thickness of the heat conduction member 14. The porous thermal conductor 15 that constitutes the heat conduction member 14 is a material that is likely to be partially missing due to thermal deformation or vibration of the circuit board 3. However, since the protruding portion 13 has a structure that covers substantially the entire thickness of the porous thermal conductor 15, it is possible to prevent the missing portion of the porous thermal conductor 15 from being scattered on the circuit board 3. The protruding portion 13 preferably covers substantially the entire thickness of the porous thermal conductor 15.

The low elasticity heat dissipation material 10b is formed between the heat conduction member 14 and the thick portion 13b of the case main body 1 constituting the cooling mechanism, and is thermally coupled to the heat conduction member 14 and the thick portion 13b. The low elasticity heat dissipation material 10a is formed between the surface 49 of the heat generating component 4 and the heat conduction member 14, and is thermally coupled to the heat generating component 4 and the heat conduction member 14. Further, the low elasticity heat dissipation material 10c is formed between the lower back portion 44a of the heat generating component 4 and the top surface 13a of the protruding portion 13, and between an outer peripheral side surface between the surface 49 of the heat generating component 4 and the lower back portion 44a and the inner peripheral side surface of the protruding portion 13, and is thermally coupled to the peripheral portion of the heat generating component 4 and the protruding portion 13.

Therefore, heat generated by the heat generating component 4 is thermally transferred to the case main body 1 constituting the cooling mechanism and is cooled via the heat dissipation unit 5 including the low elasticity heat dissipation material 10a, the heat conduction member 14, and the low elasticity heat dissipation material 10b. The heat conduction member 14 includes the porous thermal conductor 15 having a higher thermal conductivity than a resin including a filler with excellent thermal conductivity, and includes the low elasticity heat dissipation material filled in the pores 15a of the heat conduction member 14. Therefore, a cooling capacity for cooling the heat generating component 4 via the case main body 1 can be improved. Further, the heat generated by the heat generating component 4 is thermally transferred to the case main body 1 via the low elasticity heat dissipation material 10c formed between the top surface 13a of the protruding portion 13 and the peripheral portion of the heat conduction member 14. The configuration further improves the cooling capacity for the heat generating component 4.

In the electronic control device 100, due to a difference in thermal expansion coefficients of the heat generating component 4 and the circuit board 3, deformation including warpage or the like occurs in the circuit board 3 as an environmental temperature changes. Further, vibration is transmitted to the electronic control device 100 mounted on a vehicle or the like. The electronic control device 100 includes the low elasticity heat dissipation materials 10a, 10b, and 10c that have flexibility and deform following thermal deformation or vibration of the circuit board 3. Therefore, a load acting on the heat generating component 4 due to the deformation or vibration caused by heat is absorbed by the low elasticity heat dissipation materials 10a, 10b, and 10c so that the load applied to the heat generating component 4 is reduced. Therefore, it is possible to prevent the heat generating component 4 from being damaged and to prevent characteristics from being deteriorated, and to improve reliability.

### Example 1

The electronic control device 100 having an appearance shown in FIG. 1 and shown in the cross-sectional view of FIG. 2 was manufactured using the following members. The circuit board 3 was fixed to the boss portions 7 provided at four corner portions of the case main body 1 by the screws 8.

The heat generating component 4 was formed as a ball grid array (BGA) semiconductor device of 31 mm×31 mm×3.1 mm (thickness) and was mounted on the circuit board 3 by soldering.

The circuit board 3 was formed of an FR4 material having a size of 187 mm×102.5 mm×1.6 mm (thickness). A thermal conductivity of the circuit board 3 is 69 W/mK in an in-plane direction and 0.45 W/mK in a vertical direction.

The case main body 1 is formed using an ADC 12 having a thermal conductivity of 96 W/mK and an emissivity of 0.8.

The cover 2 was formed using a sheet metal having a thermal conductivity of 65 W/mK.

In the heat dissipation unit 5, the heat conduction member 14 was formed by filling a low elasticity heat dissipation material (thermal conductivity 2 W/mK) including a thermally conductive filler in a silicon-based resin to the porous thermal conductor 15 having a porosity of 90% which is made of aluminum (thermal conductivity 237 W/mK). An outer periphery of the heat conduction member 14 was covered with the low elasticity heat dissipation materials 10a, 10b, and 10c (thickness of each of the low elasticity heat dissipation materials 10a, 10b, and 10c is equal to or larger than 100 μm) formed of the same material, so that the sheet-shaped heat dissipation unit 5 having a thermal conductivity of 25 W/mK is formed at a dimension of 31 mm×31 mm×1.9 mm (thickness).

As Comparative Example 1, an electronic control device using a heat conduction member formed of only a mixed material including the thermally conductive filler in the silicon-based resin was manufactured. A thermal conductivity of the heat conduction member formed of the silicon-based resin is 2 W/mK, and an area and a thickness thereof are the same as those in Example 1. Further, an appearance and a structure of a cross section of the electronic control device of the comparative example is the same as those in Example 1.

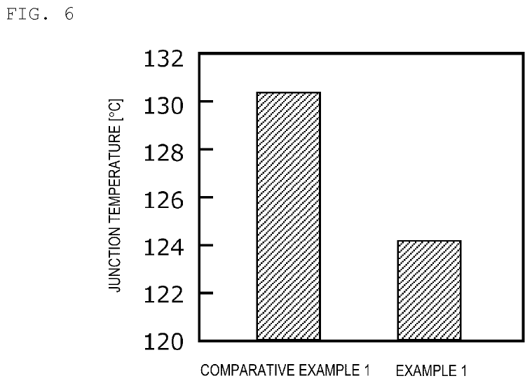

FIG. 6 is a diagram showing a heat dissipation effect obtained by the embodiment according to the invention.

FIG. 6 shows junction temperatures of heat generating components 4 of the electronic control device 100 of Example 1 and the electronic control device of Comparative Example 1. The junction temperatures shown in FIG. 6 are temperatures in a windless environment and at an environmental temperature of 85° C. when amounts of heat generation of the entire electronic control devices are set to be 20 W (including amounts of heat generation of the heat generating components 4 of 9 W). As shown in FIG. 6, the junction temperature of the heat generating component 4 of Example 1 is lower than the junction temperature of the heat generating component 4 of Comparative Example 1. The junction temperature is a temperature of a substantially central portion JT on a side surface on an outer peripheral side of the semiconductor chip 41 constituting the heat generating component 4 shown in FIG. 4.

Further, when the warpage of the circuit board 3 when the environmental temperature is changed from −40 to 120° C. is verified by thermal stress analysis, a maximum amount of substrate deformation is substantially 60 μm. Therefore, according to the electronic control device 100 of Example 1 including the heat dissipation unit 5 including the low elasticity heat dissipation materials 10a, 10b, and 10c each having a thickness of 100 μm or more, it is confirmed that the load acting on the heat generating component 4 due to thermal deformation of the circuit board 3 can be sufficiently reduced.

The above-described first embodiment shows that the heat dissipation unit 5 includes the heat conduction member 14 and the low elasticity heat dissipation material 10 and the low elasticity heat dissipation material 10 includes the low elasticity heat dissipation materials 10a, 10b, and 10c. However, the low elasticity heat dissipation material 10 may include only the low elasticity heat dissipation material 10a formed between the heat conduction member 14 and the surface 49 of the heat generating component 4 on the side opposite to the circuit board 3 side.

Further, the heat conduction member 14 is shown as a member in which the low elasticity heat dissipation material is filled in each of the pores 15a of the porous thermal conductor 15. However, the heat conduction member 14 may be constituted only by the porous thermal conductor 15 in which the low elasticity heat dissipation material is not filled in the pores 15a.

According to the embodiment of the invention, the following effects can be achieved.

(1) The electronic control device 100 includes the heat dissipation unit 5 thermally coupled to the surface 49 of the heat generating component 4 on a side opposite to the circuit board 3 side and a cooling mechanism thermally coupled to the heat dissipation unit 5. The heat dissipation unit 5 includes the porous thermal conductor 15 and the low elasticity heat dissipation material (semi-cured resin) 10a which includes a heat conductive filler and is formed between at least the porous thermal conductor 15 and the surface 49 of the heat generating component 4. Therefore, a cooling capacity for the heat generating component 4 can be improved by the heat dissipation unit 5 and the load acting on the heat generating component 4 due to deformation or vibration of the circuit board 3 caused by heat can be reduced. Accordingly, it is possible to prevent the heat generating component 4 from being damaged and to prevent characteristics from being deteriorated, and to improve reliability.

(2) The heat dissipation unit 5 includes the low elasticity heat dissipation material (semi-cured resin) 10b which includes the heat conductive filler and is formed between the porous thermal conductor 15 and the cooling mechanism. Therefore, the load acting on the heat generating component 4 due to the deformation or vibration caused by heat can be further reduced.

(3) The low elasticity heat dissipation material (semi-cured resin) including the heat conductive filler is filled in the pores 15a of the porous thermal conductor 15. Therefore, thermal conductivity of the porous thermal conductor 15 can be further improved and cooling capacity for the heat generating component 4 can be improved.

(4) The porous thermal conductor 15 covers an entire region of the surface 49 of the heat generating component 4. Therefore, a thermal coupling area between the heat generating component 4 and the porous thermal conductor 15 can be improved and the cooling capacity can be improved.

(5) The protruding portion 13 surrounding an outer periphery of the porous thermal conductor 15 and extending to the circuit board 3 side is provided on a surface of the cooling mechanism on a heat generating component 4 side. Accordingly, it is possible to prevent a missing portion of the porous thermal conductor 15 from being scattered on the circuit board 3.

(6) The heat generating component 4 includes the lower back portion 44a having a thickness smaller than that of a central portion on a peripheral portion on the surface 49 side. The low elasticity heat dissipation material (semi-cured resin) 10c including the heat conductive filler is formed between the top surface 13a of the protruding portion 13 and the lower back portion 44a of the heat generating component 4. Therefore, heat generated by the heat generating component 4 is thermally transferred to the case main body 1 via the low elasticity heat dissipation material 10c formed between the top surface 13a of the protruding portion 13 and an end portion of the heat conduction member 14, and the cooling capacity for the heat generating component 4 is further improved.

### Second Embodiment

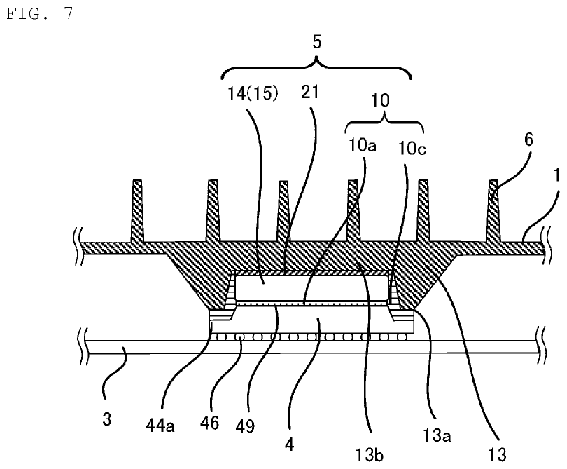

FIG. 7 is a cross-sectional view showing a second embodiment of the heat dissipation structure according to the invention.

The electronic control device 100 according to the second embodiment includes a structure in which the low elasticity heat dissipation material 10b formed between the heat conduction member 14 and the thick portion 13b of the case main body 1 in the first embodiment is replaced with a solder layer 21.

The heat generating component 4 and the thick portion 13b of the case main body 1 are bonded and fixed by the solder layer 21.

In the structure, the low elasticity heat dissipation material 10 includes the low elasticity heat dissipation materials 10a and 10c, and does not include the low elasticity heat dissipation material 10b in the first embodiment. Further, the heat dissipation unit 5 includes the heat conduction member 14, the low elasticity heat dissipation material 10, and the solder layer 21.

Other structures in the second embodiment are the same as those in the first embodiment and corresponding members are denoted by the same reference numerals and description thereof is omitted.

In the second embodiment, the heat conduction member 14 may include the porous thermal conductor 15 in which a low elasticity heat dissipation material is filled in the pores 15a, and may include the porous thermal conductor 15 in which the low elasticity heat dissipation material is not filled in the pores 15a.

Even in the second embodiment, the electronic control device 100 includes the porous thermal conductor 15 and the low elasticity heat dissipation material (semi-cured resin) 10a which includes the heat conductive filler and is formed between the porous thermal conductor 15 and the surface 49 of the heat generating component 4. Therefore, the same effect as the effect (1) of the first embodiment is obtained.

### Third Embodiment

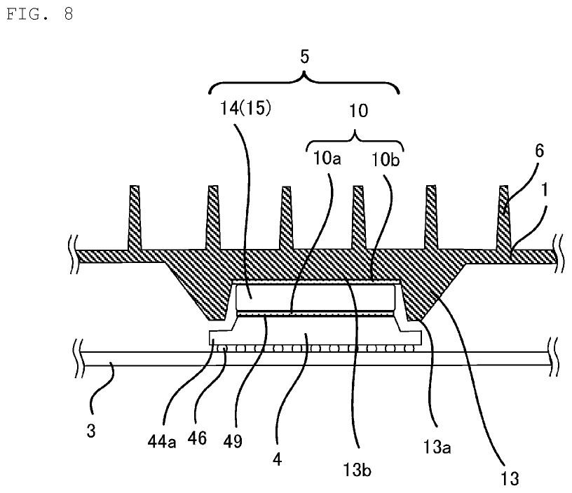

FIG. 8 is a cross-sectional view showing a third embodiment of the heat dissipation structure of the invention.

The electronic control device 100 according to the third embodiment includes a structure that does not include the low elasticity heat dissipation material 10c in the first embodiment formed between a peripheral portion of the heat generating component 4 and the protruding portion 13.

That is, in the third embodiment, the heat dissipation unit 5 includes the heat conduction member 14 and the low elasticity heat dissipation material 10 including the low elasticity heat dissipation materials 10a and 10b.

Other structures in the third embodiment are the same as those in the first embodiment and corresponding members are denoted by the same reference numerals and description thereof is omitted.

In the third embodiment, the heat conduction member 14 may include the porous thermal conductor 15 in which a low elasticity heat dissipation material is filled in the pores 15a, and may include the porous thermal conductor 15 in which the low elasticity heat dissipation material is not filled in the pores 15a.

Even in the third embodiment, the electronic control device 100 includes the porous thermal conductor 15 and the low elasticity heat dissipation material (semi-cured resin) 10a which includes the heat conductive filler and is formed between the porous thermal conductor 15 and the surface 49 of the heat generating component 4. Therefore, the same effect as the effect (1) of the first embodiment is obtained.

### (Modification of Heat Generating Component)

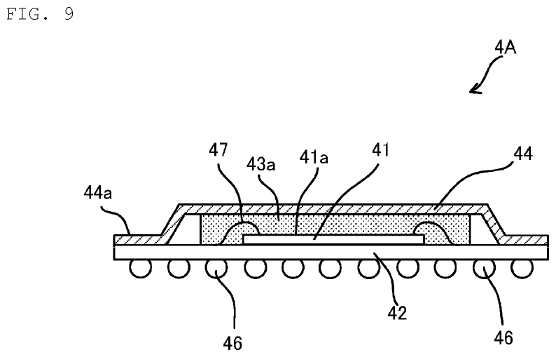

FIG. 9 is a cross-sectional view showing a modification of the heat generating component 4 shown in FIG. 4.

A heat generating component 4A shown in FIG. 9 is also a BGA semiconductor device and includes a structure in which the semiconductor chip 41 is face-up mounted on the substrate 42.

That is, the semiconductor chip 41 is die-bonded on the substrate with the main surface 41a on which an integrated circuit is formed facing a side opposite to the substrate 42, and is connected to the substrate 42 by a bonding wire 47. A sealing resin 43a is formed between the semiconductor chip 41 and the lid 44. The other structures of the heat generating component 4A are the same as those of the heat generating component 4 and corresponding members are denoted by the same reference numerals and description thereof will be omitted. Such a heat generating component 4A can also be replaced with the heat generating components 4 shown in the first to third embodiments.

### Fourth Embodiment

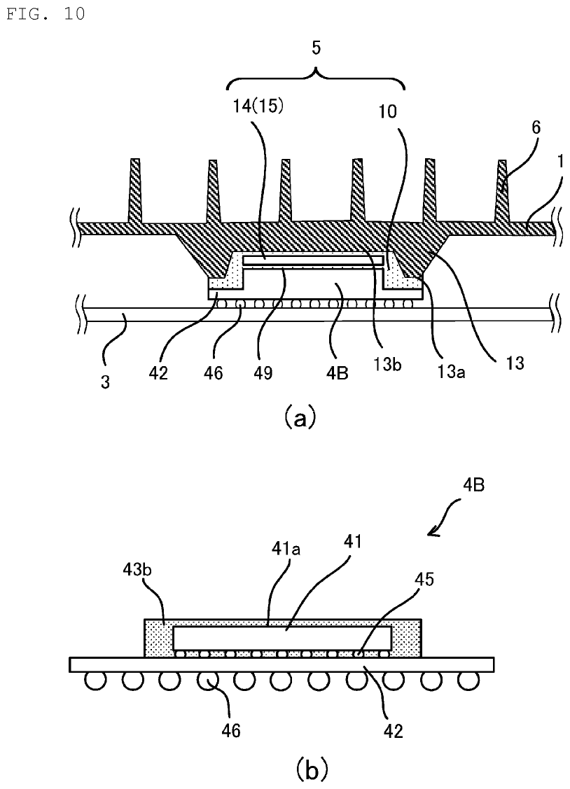

FIG. 10(a) is a cross-sectional view showing a fourth embodiment of the heat dissipation structure according to the invention, and FIG. 10(b) is an enlarged view of a heat dissipation component shown in FIG. 10(a).

As shown in FIG. 10(b), a heat generating component 4B in the fourth embodiment is a BGA semiconductor device which does not include the metal lid 44. The semiconductor chip 41 of the heat generating component 4B is flip-chip mounted on the substrate 42 by the bonding material 45 such as solder. The entire semiconductor chip 41 mounted on the substrate 42 is sealed with a sealing resin 43b.

As shown in FIG. 10(a), in the heat generating component 4B, the sealing resin 43b is disposed in the protruding portion 13 facing the thick portion 13b. In this state, a peripheral portion of the substrate 42 of the heat generating component 4B is disposed at a position corresponding to the top surface 13a of the protruding portion 13. The heat conduction member 14 is disposed between the heat generating component 4B and the thick portion 13b of the case main body 1. The heat conduction member 14 includes the porous thermal conductor 15 in which a low elasticity heat dissipation material is filled in the pores 15a or the porous thermal conductor 15 in which the low elasticity heat dissipation material is not filled in the pores 15a. The low elasticity heat dissipation material 10 is formed between the heat conduction member 14 and the thick portion 13b of the case main body 1, between the surface 49 of the heat generating component 4B and the heat conduction member 14, between the peripheral portion of the substrate 42 of the heat generating component 4B and the top surface 13a of the protruding portion 13, and between a peripheral side of the sealing resin 43b of the heat generating component 4 and an inner peripheral side surface of the protruding portion 13.

Other structures in the fourth embodiment are the same as those in the first embodiment and corresponding members are denoted by the same reference numerals and description thereof is omitted.

Even in the fourth embodiment, the electronic control device 100 includes the porous thermal conductor 15 and the low elasticity heat dissipation material (semi-cured resin) 10 which includes a heat conductive filler and is formed between the porous thermal conductor 15 and the surface 49 of the heat generating component 4. Therefore, the same effect as the effect (1) of the first embodiment is obtained.

In the above-described embodiments, a cooling mechanism is exemplified as a structure in which the heat dissipation fins 6 are provided on the case main body 1. However, a cooling mechanism that simply performs cooling with a cooling liquid without the heat dissipation fins 6 may be used.

In the above-described embodiments, the heat generating components 4, 4A, and 4B are exemplified as BGA semiconductor devices. However, the invention can be applied to a heat dissipation structure of a semiconductor device other than the BGA semiconductor device.

In the above-described embodiments, a structure is exemplified in which the protruding portion 13 surrounding an outer periphery of the porous thermal conductor 15 is provided on a surface on a heat generating component 4 side of the cooling mechanism. However, the protruding portion 13 is not always necessary. Further, in the above-described embodiments, a structure is exemplified in which an inner region of the protruding portion 13 serves as the thick portion 13b thicker than a periphery of the protruding portion 13. However, the thick portion 13b may not be formed in the inner region of the protruding portion 13.

Although various embodiments and modifications are described above, the invention is not limited thereto. Other embodiments conceivable within the scope of the technical idea of the invention are also included in the scope of the invention.

A disclosed content of the following priority basic application is incorporated herein by reference.

Japanese Patent Application No. 2017-237265 (filed on Dec. 11, 2017).

### REFERENCE SIGN LIST

1 case main body (cooling mechanism)
3 circuit board (substrate)
4, 4A, 4B heat generating component
5 heat dissipation unit
10, 10a, 10b, 10c low elasticity heat dissipation material (semi-cured resin)
13 protruding portion
13a top surface
13b thick portion
14 heat conduction member
15 porous thermal conductor
15a pore
21 solder layer
41 semiconductor chip
44a lower back portion
49 surface
100 electronic control device

1. An electronic control device comprising:
a substrate;
a heat generating component mounted on the substrate;
a heat dissipation unit thermally coupled to a surface of the heat generating component located on a side opposite to the substrate side; and
a cooling mechanism thermally coupled to the heat dissipation unit, wherein
the heat dissipation unit includes:
a porous thermal conductor; and
a semi-cured resin which includes a heat conductive filler and is formed between at least the porous thermal conductor and the surface of the heat generating component.

2. The electronic control device according to claim 1, wherein
the heat dissipation unit further includes a semi-cured resin which includes a heat conductive filler and is formed between the porous thermal conductor and the cooling mechanism.

3. The electronic control device according to claim 1, wherein
the heat dissipation unit further includes a solder layer formed between the porous thermal conductor and the cooling mechanism.

4. The electronic control device according to claim 1, wherein
a semi-cured resin including a heat conductive filler is filled in a pore of the porous thermal conductor.

5. The electronic control device according to claim 1, wherein
the porous thermal conductor covers an entire region of the surface of the heat generating component.

6. The electronic control device according to claim 1, wherein
a protruding portion surrounding an outer periphery of the porous thermal conductor and extending to the substrate side is provided on a surface of the cooling mechanism on the heat generating component side.

7. The electronic control device according to claim 6, wherein
the heat generating component includes a lower back portion having a thickness smaller than that of a central portion on a peripheral portion on the surface side, and
a semi-cured resin including a heat conductive filler is formed between a top surface of the protruding portion and the lower back portion of the heat generating component.

8. The electronic control device according to claim 7, wherein
the top surface of the protruding portion is disposed closer to the lower back portion side than the surface of the central portion of the heat generating component.

9. The electronic control device according to claim 6, wherein
the protruding portion is formed to cover an outer periphery of the heat generating component, and a semi-cured resin including a heat conductive filler is formed between a top surface of the protruding portion and a peripheral portion of the heat generating component.

10. The electronic control device according to claim 9, wherein
the top surface of the protruding portion is disposed closer to the substrate side than the surface of the heat generating component.

11. The electronic control device according to claim 7, wherein
an inner region of the protruding portion is formed to be thicker than an outer periphery side region of the protruding portion.
